(19) United States
(12) Patent Application Publication
(10) Pub. No.: US 2004/0183518 A1
(43) Pub. Date: Sep. 23, 2004

(54) Apparatus and method for clock recovery and eye diagram generation

(76) Inventors: Dennis J. Weller, Colorado Springs, CO (US); Steven D. Draving, Colorado Springs, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/391,908

(22) Filed: Mar. 19, 2003

(51) Int. Cl. G01R 13/34

(52) U.S. Cl. 324/76.58

(57) ABSTRACT

A digital storage oscilloscope that has a port for receiving a signal, having an embedded clock signal, and a processor, configured by software to recover the embedded clock signal from the signal. In a preferred embodiment, the processor implements a digital PLL to recovered embedded clock signal. In a further preferred embodiment the processor uses the recovered embedded clock signal to generate an eye diagram that graphically portrays jitter in the data signal.

### BACKGROUND OF THE INVENTION

As digital systems become faster and more complex, test and measurement systems that monitor performance and diagnose problems must also become faster and more complex. Current fiber-optic telecommunication systems can move data worldwide at 10 Gb/s, with future systems easily reaching beyond 100 Gb/s. While the information on such networks is digital in nature, the actual signals are analog. To design, characterize, and troubleshoot gigabit-per-second systems, engineers need to measure a variety of characteristics of the signal, including amplitude, rise/falltime, jitter, over/undershoot, ringing, long-term droop, etc. To make such measurement, engineers generally use an oscilloscope, and in particular real-time digital storage oscilloscopes (often referred to as DSO's).

A common time domain measurement produced by a DSO is an eye diagram. The eye diagram is a plot of data points repetitively sampled from a pseudo-random bit sequence and displayed by an oscilloscope. In other words, the DSO acts like a multiple-exposure camera, continually superimposing a signal segment over prior segments. The DSO acquires each segment based on a data clock pulse associated with the signal. With each clock trigger, a new waveform is measured and overlaid upon all previous measured waveforms. The time window of observation is typically two data periods wide. For example, for 10 Gb/s, the period is 100 ps, and the time window is set to 200 ps. An eye diagram allows the user to observe system performance on a single plot.

It has become common to combine the data signal with its associated clock signal prior to transmission of the data signal. Such combining is thought to reduce jitter, simplify interconnection and to permit, among other things, continuous correction of drift errors. This approach requires costly circuitry (in terms of both dollars and space) on both transmit and receive ends to combine and separate the signals. For example, phase locked loops (PLL's) are generally added to receive circuits to recover the clock stream. This has, of course, required that DSOs be teamed with dedicated clock recovery circuitry to analyze the signal.

FIG. 1 is a block diagram of a known system 100 for generating an eye diagram by triggering from a recovered clock signal. In this case, an optical signal 10, such as a SONET signal, is presented for analysis. An optical coupler 12 splits the signal, supplying the signal to the vertical input of a DSO 16 and the input of a lightwave clock/data receiver 14, such as the AGILENT 83446A. The lightwave clock/data receiver 14 extracts clock and data information from digitally modulated lightwave signals. The output of the lightwave clock/data receiver 14 is supplied to the clock input of the DSO 16. The AGILENT 83446A also has a data output circuit that, for many application, can also supply the data signal to the DSO 16.

It is also known to provide clock recovery circuitry in a DSO itself, but this creates several problems. Significantly, clock recovery circuits are, in and of themselves, a source of jitter. Further, such circuits are, by design, limited to a range of data signal rates, requiring multiple clock recovery circuits to support the broad range of data signal rates in use today. Further, clock recovery circuits are expensive and space consuming, increasing the cost of the DSO beyond attractive price points.

Accordingly, the present inventors have recognized a need for new DSO apparatus and methods capable of generating eye diagrams without the need for expensive dedicated clock recovery circuits.

### BRIEF DESCRIPTION OF THE DRAWINGS

An understanding of the present invention can be gained from the following detailed description of the invention, taken in conjunction with the accompanying drawings of which:

FIG. 1 is a block diagram of a known system for generating an eye diagram by triggering from a recovered clock signal.

FIG. 2 is a general block diagram of a real-time digital storage oscilloscope.

FIG. 3 is a sample of an eye diagram produced in accordance with a preferred embodiment of the present invention.

FIG. 4 is a sample of an intensity graded eye diagram in accordance with a preferred embodiment of the present invention.

### DETAILED DESCRIPTION

Reference will now be made in detail to the present invention, examples of which are illustrated in the accompanying drawings, wherein like reference numerals refer to like elements throughout. The detailed description which follows presents methods that may be embodied by routines and symbolic representations of operations of data bits within a computer readable medium, associated processors, digital storage oscilloscopes, general purpose personal computers configured with data acquisition cards and the like. A routine is here, and generally, conceived to be a sequence of steps or actions leading to a desired result, and as such, encompasses such terms of art as “program,” “objects,” “functions,” “subroutines,” and “procedures.” These descriptions and representations are the means used by those skilled in the art effectively convey the substance of their work to others skilled in the art.

In general, the sequence of steps in the present methods require physical manipulation of physical quantities. These quantities take the form of optical, electrical or magnetic signals capable of being stored, transferred, combined, compared or otherwise manipulated. Those of ordinary skill in the art conveniently refer to these signals as “bits”, “values”, “elements”, “symbols”, “characters”, “images”, “terms”, “numbers”, or the like. It should be recognized that these and similar terms are to be associated with the appropriate physical quantities and are merely convenient labels applied to these quantities.

The methods of the present invention will be described with respect to implementation on a digital storage oscilloscope, but the methods recited herein may operate on a general purpose computer or other network device selectively activated or reconfigured by a routine stored in the computer and interface with the necessary signal processing capabilities. More to the point, the methods presented herein are not inherently related to any particular device, rather, various devices may be used with routines in accordance with the teachings herein. Machines which may perform the functions of the present invention include those manufactured by such companies as AGILENT TECHNOLOGIES, INC., HEWLETT PACKARD, and TEKTRONIX, INC. as well as other manufacturers of signal analysis equipment.

With respect to the software described herein, those of ordinary skill in the art will recognize that there exists a variety of platforms and languages for creating software for performing the procedures outlined herein. The preferred embodiment of the present invention can be implemented using any of a number of varieties of C, however, those of ordinary skill in the art also recognize that the choice of the exact platform and language is often dictated by the specifics of the actual system constructed, such that what may work for one type of system may not be efficient on another system. It should also be understood that the routines and calculations describe in this invention are not limited to being executed as software on a computer or DSP (Digital Signal Processor), but can also be implemented in a hardware processor. For example, the routines and calculations could be implemented with HDL (Hardware Design Language) in an ASIC.

In accordance with the present invention, an eye diagram is generated based on a digital signal having an embedded clock signal using software based clock recovery methods. The digital signal can be encoded using any of a number of conventions, including non-return to zero (NRZ) level or inverted, return to zero (RZ), multilevel binary and biphase. The clock signal of the digital signal may be extracted using any of a number of software-based methods. The preferred embodiments of the present invention use a digital PLL. As used herein the term digital PLL encompasses both software based and digital hardware PLL's. Preferably, instructions to perform the extraction of the clock signal are stored as software on a real time digital storage oscilloscope, such as the AGILENT 54855A. Digital PLL's are discussed in: Best, Dr. Roland E, Phase-Locked Loops Theory, Design, and Application, McGraw-Hill, 1984, incorporated herein by reference. Alternative software based clock recovery methods, known to those of ordinary skill in the art, such as non-PLL or fixed recovery methods, may be used to recover the clock signal in accordance with at least one preferred embodiment.

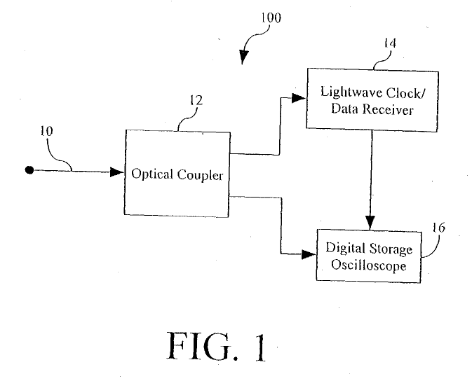

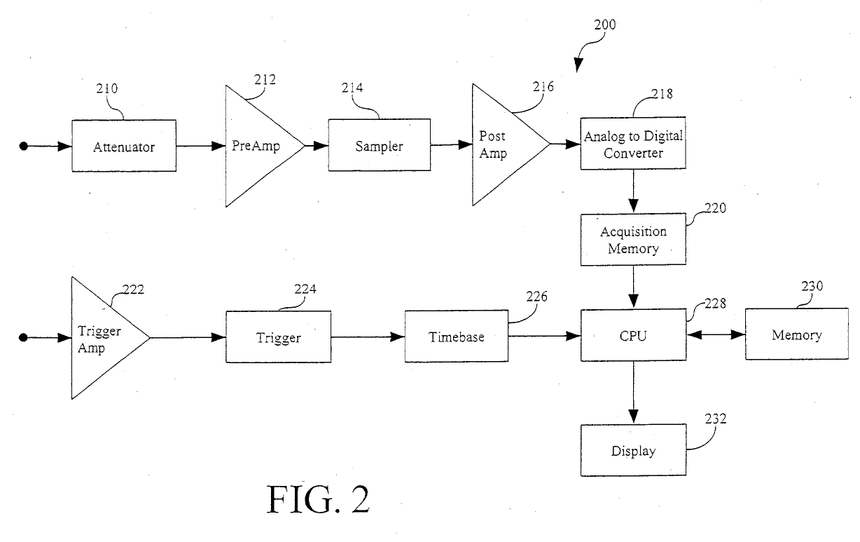

FIG. 2 is a general block diagram of a real time digital storage oscilloscope 200. It is to be noted that the block diagram shown in FIG. 1 has been simplified to avoid obscuring the present invention. There are functional components that have been left out or conveniently combined with other functional components selected for inclusion in FIG. 2. The DSO 200 may be embodied by any number of available DSO's including AGILENT 54855A.

Data signals are input via vertical input and conditioned by an attenuator 210 and a preamplifier 212. A sampler 214 extracts samples at discrete instances in time from the data signal. The samples are subsequently amplified by a post amp 216, digitized by an analog to digital converter 218 and stored in an acquisition memory 220.

If supplied, a trigger signal is conditioned by a trigger amp 222 prior to submission to a trigger unit 224. The trigger unit 224 outputs trigger events determining where the displayed acquisition starts and stops. The time period acquired is determined by the timebase 226. A CPU 228, operating in accordance with instructions stored in a memory 230, retrieves a series of digitized values from the acquisition memory 220 based on the trigger indication and the time period. The CPU 228 performs any requested processing and displays the resultant image on the display 232.

In operation, the real-time DSO 200 continuously acquires data at the sampling frequency and stores it in the acquisition memory 220 in a first-in-first-out sequence. When a trigger event is identified, the acquisition is stopped, the CPU 228 reads the acquisition memory 220 and displays points on the display 232 corresponding to voltage of the signal. The present invention relates to, among other things, the identification of trigger events when the data signal, as supplied to the DSO 200, has an embedded clock signal.

In accordance with a preferred embodiment of the present invention, the CPU 228 recovers the clock signal using digital PLL methods. Specifically, the CPU 228 generates a clock record representing the recovered clock signal as a function of time. The DSO 200 transforms the data signal into discrete time data records stored in the acquisition memory 220. Each time data record represents the data signal's voltage as a function of time. We can represent the data record as data_signal(n), wherein each value of n represents a point in time. The CPU 228, in accordance with a preferred embodiment of the present invention, processes data_signal(n) using one or more digital PLL methods to generate a clock record representing the recovered clock signal as a function of time. We can represent the clock signal record as clock_signal(n), wherein each value of n represents the same point in time as the n in data_signal(n). Thus for each value of n we can retrieve a data_signal value and a clock_signal value. Preferably, the value of clock_signal(n) will be zero for all values of n, except for values of n that represent a trigger event. In perhaps the preferred embodiment, rising edges of the clock signal are used as the trigger events.

To generate an eye diagram, the CPU 228 would search through clock_signal(n) identifying values of n where trigger events occur. Preferably, a certain portion of the clock_signal(n), and hence the data_signal (n), is skipped to allow for the digital PLL to settle. Typically, settling takes around 5/wn for a critically damped PLL to settle to within 0.1 UI (unit interval), where wn is the natural frequency in radian/sec. Using a typical Fibre Channel data communication link as an example, 625 nS would be required to permit settling of the digital PLL. This of course requires that the DSO 200 have enough acquisition memory 220 to hold at least 625 nS of the data signal. A real time DSO sampling at a rate of 10 Gsa/sec would require a memory size of at least 6,250 samples.

For each value of n that represents a trigger point, the CPU 228 displays a segment of the data_signal(n) starting prior to the trigger point (n-x) and ending after the trigger point (n+y), such that the trigger point for each segment occurs at the same time reference point on the display. As noted above, each subsequent segment is simultaneously overlaid to produce an eye diagram.

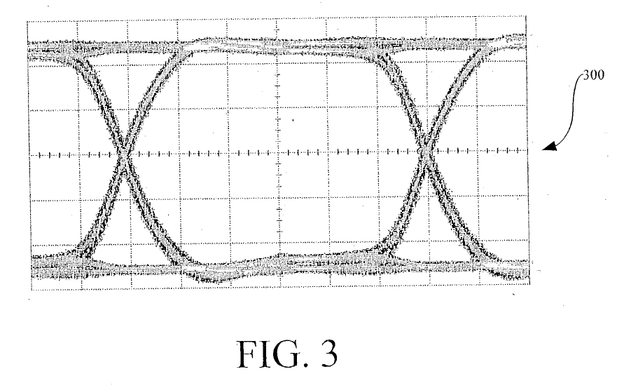

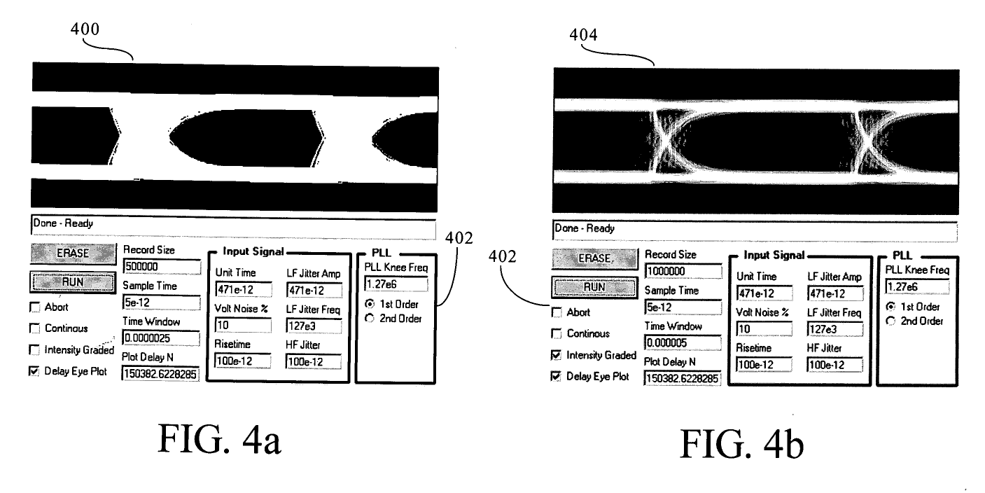

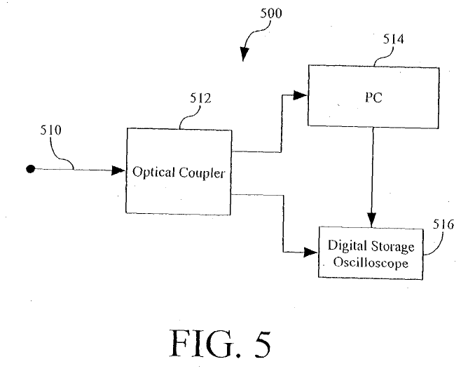

A sample eye diagram 300 is shown in FIG. 3. FIG. 4a is an illustration of a display of a DSO while an eye diagram is being displayed. The display includes the eye diagram 400 and user interface 402. To avoid obscuring the present invention, the details of the user interface are not further discussed herein, suffice to say, those of ordinary skill in the art will recognize the salient details from the images shown in FIGS. 3 and 4.

One popular variation of the eye diagram is the intensity graded eye diagram wherein areas in the waveform that are being hit more often are highlighted. The intensity grading's highlighting often shows distinct edges in the waveform that are jittered. These distinct edges or modes indicate data pattern dependencies in the transmitter. An intensity graded eye diagram 404 is shown in FIG. 4b in conjunction with the appropriate changes in the user interface 402.

FIG. 5 is a block diagram of apparatus in accordance with the second preferred embodiment of the present invention for performing method in accordance with the preferred embodiment of the present invention. In this case, an optical signal 510, such as a SONET signal, is presented for analysis. An optical coupler 512 splits the signal, supplying the signal to the vertical input of a DSO 516 and the input of a suitably configured PC 514. In particular, the PC 514 is configured with an off-the-shelf signal capture card that digitizes the data signal. The PC 514 recovers the embedded clock signal from the lightwave signals, using a digital PLL in accordance with the preferred methods of the present invention as described herein above. The PC 514 supplies a data stream to the DSO 16 representing the recovered clock signal. This can either be in the form of a digital record, such as clock_signal(n) described above, or in the form of a reconstituted clock signal supplied to the clock input of the DSO 516.

The software to implement the soft-PLL used for clock recovery can take many forms, see: Best, Dr. Roland E, Phase-Locked Loops Theory, Design, and Application, McGraw-Hill, 1984, incorporated herein by reference. The following is an example of a procedure to recover a clock signal from a non-return to zero data signal:

Sub recover_clock(data_signal, clock_signal, ByVal record_size,
ByVal sample_time, ByVal PLL_freq,
ByVal PLL_order, ByVal PLL_damping, ByVal clock_freq As Double, ByVal threshold)

| ‘ This procedures recovers the clock_signal( ) from a NRZ data_signal( ), | |
|---|---|
| ‘ using a software implementation of a PLL, either 1st or 2nd order | |
| ‘ determined PLL_order. A clock_signal( ) = 1 | |
| ‘ represents a rising clock edge location | |
| ‘ PLL_freq is the natural or response knee frequency, | |
| ‘ PLL_damping is the damping factor. | |
| ‘ clock_freq is the starting frequency, IN RADIANS/s, for the PLL, and must be | |
| ‘ within 0.1% of target for 2nd order PLL to lock | |
| ‘ Threshold is the data_signal( ) value that represent and edge crossing | |
| ‘ | |
| ‘ Calculate phase locked loop variables | |
| ‘ | |
| Dim Kpd As Single | ‘ phase detector gain |
| Kpd = 1 | ‘ use 1 for simplicity |
| Dim Kvco As Single | ‘ vco gain, output in radians/sec |
| Kvco = 1 | ‘ use 1 for simplicity |

| | |
|---|---|
| Dim loop_filter As Double | ‘ output of integrated component of loop filter |
| loop_filter = clock_freq / Kvco | ‘ init loop filter output to starting frequency |
| Dim tau1, tau2 As Single | ‘ loop filter time constants |

| ‘ | |
|---|---|
| ‘ 2nd order loop filter function is = ( 1 + jw * tau2 ) / (jw * tau1) | |
| ‘ | |
| tau1 = Kpd * Kvco / (TWOPI * PLL_freq) \hat{ } 2 | ‘calculate tau1 |
| tau2 = PLL_damping * 2 * (tau1 / (Kpd * Kvco)) \hat{ } 0.5 ‘ | calculate tau2 |

| ‘ | |
|---|---|
| ‘ Clock Recovery Loop... | |
| ‘ | |
| Dim clock_phase As Double | ‘ clock phase in radians |
| clock_phase = Rnd * TWOPI | ‘ init starting clock phase randomly |
| Dim phase_error As Double | ‘ phase detector output |
| phase_error = 0 | ‘ initialized starting phase error to zero |
| Dim i As Long | |
| clock_signal(1) = 0 | ‘ no clock edge in first location |

```
For i = 2 To record_size
  ‘
  ‘ increment clock phase and store clock_signal( )
  ‘
  clock_phase = clock_phase + sample_time * clock_freq
  If clock_phase >= TWOPI Then
    clock_phase = clock_phase − TWOPI
    clock_signal(i) = 1
  Else
    clock_signal(i) = 0
  End If
  ‘
  ‘ Update phase_error if a data edge was detected
  ‘
  If ((data_signal(i) >= threshold And data_signal(i − 1) < threshold)) Or
  (data_signal(i) < threshold
```

And data_signal(i − 1) >= threshold) Then

```
    phase_error = Kpd * (clock_phase − PI)
  End If
  phase_signal(i) = phase_error / Kpd / PI ‘ store phase error in array for plotting
  ‘
  If PLL_order = 2 Then
    ‘
    ‘ 2nd order PLL calculations...
    ‘ Calculate change to loop filter integrated output component
    ‘
    loop_filter = loop_filter − phase_error * sample_time / tau1
    ‘
    ‘ Calculate new clock frequency, including loop filter phase component
    ‘
    clock_freq = Kvco * (loop_filter − phase_error * tau2 / tau1)
    ‘
  ElseIf PLL_order = 1 Then
    ‘
    ‘ 1st order PLL calculations − loop gain must be TWOPI * PLL_freq
    ‘ Calculate new clock frequency, including loop filter phase component
    ‘
    clock_freq = Kvco * (loop_filter − phase_error * TWOPI * PLL_freq)
    ‘
  End If
Next i
```

End Sub

This procedure could also be modified, by those of ordinary skill in the art, so as to be integrated into digital hardware forming a digital hardware PLL.

In perhaps the preferred embodiments, the recovered clock signal is used to generate an eye diagram graphically portraying the jitter present in the data signal. Eye diagram software using conventional clock signals is well known in the art. The present invention using a clock record, such as clock_signal described hereinabove rather than a traditional clock signal. For purposes of completeness, and by way of example, the following is presented as an example of a procedure for drawing an eye diagram based on a data signal and the clock_signal variable loaded in the prior procedure (transferred into the procedure as the clock_edges variable):

```
Sub draw_eye(data_signal, clock_edges, ByVal record_size, ByVal
width, ByVal plot_delay)
  ‘
  ‘ Draw eye diagram using data in data_signal, and triggering off
  edge in
  ‘ clock_edges, represented by non-zero values.
  ‘ width sets the horizontal size in sample of the eye diagram.
  ‘ plot_delay is the number of sample to skip (while PLL is stabilizing)
  before plotting
  ‘
  Dim i, edge_count, x, y As Long
  Dim pix_increment As Single
  Dim old_x, old_y, new_x, new_y As Single
  ‘
  ‘ Draw eye diagram...
  ‘
  For i = plot_delay + width / 2 + 1 To record_size − width / 2
    ‘
    ‘ look for rising clock edge, this is a trigger point
    ‘
    If clock_edges(i) = 1 Then
      ‘
      ‘ Rising clock edge found, so draw/overlay a waveform segment,
      starting
      ‘ at width/2 before trigger, and ending iwth width/2 after trigger
      ‘
      status.Text = “Drawing Eye Waveform # ” & Int(i)
      old_x = 0
      old_y = eye.Height / 2 − eye.Height / 2 * data_{—}
      signal(i − width / 2)
      For x = (i − width / 2 + 1) To (i + width / 2)
        new_y = eye.Height / 2 − eye.Height / 2 * data_signal(x)
        new_x = old_x + eye.width / width
        eye.Line (old_x, old_y)−(new_x, new_y)
        old_x = new_x
        old_y = new_y
      Next x
    End If
  Next i
End Sub
```

The following is an example of a procedure to draw an intensity graded eye diagram using the clock_signal variable produced by the first procedure (transferred as clock_edges):

```
Sub draw_graded_eye(data_signal, clock_edges, ByVal record_size,
ByVal width, ByVal plot_delay)
  ‘
  ‘ Draw intensity gradedeye diagram using data in data_signal, and
  triggering off rising
  ‘ edges in clock_signal. width set the horizontal size in sample of the
  ‘ eye diagram. plot_delay is the number of sample to skip (while
  PLL is
  ‘ stabilizing) before plotting
  ‘
  Dim eye_map(1 To 1000, 1 To 1000) As Long
  Dim p_color As Long
  ‘
  ‘ Draw eye diagram, by finding rising clock_edges, and overlaying
  ‘ segments of data_signal from that time, segment size is width.
  ‘
  Dim i, edge_count As Long
  Dim x, y As Long
  status.Text = “clearing persistence map”
  For x = 1 To 1000
    For y = 1 To 1000
      eye_map(x, y) = 0
    Next y
    DoEvents
  Next x
  ‘
  eye.ForeColor = &HFFFFFF
  edge_count = 0
  Dim pix_increment As Single
  pix_increment = eye.width / width
  Dim old_x, old_y, new_x, new_y As Single
  p_color = 0
  For i = plot_delay + width / 2 + 1 To record_size − width / 2
    If clock_edges(i) = 1 Then ‘ look for rising clock edges
      ‘ Clock edge found
      eye.Cls
      status.Text = “drawing eye waveform i ” & i
      old_x = 0
      old_y = eye.Height / 2 − eye.Height / 2 * data_{—}
      signal(i − width / 2)
      For x = (i − width / 2 + 1) To (i + width / 2)
        new_y = eye.Height / 2 − eye.Height / 2 * data_signal(x)
        new_x = old_x + pix_increment
        eye.Line (old_x, old_y)−(new_x, new_y)
        old_x = new_x
        old_y = new_y
      Next x
      ‘ update eye persistence map
      status.Text = “updating intensity map for i ” & i
      For x = 1 To eye.width
        For y = 1 To eye.Height
          If eye.Point(x, y) Then
            eye_map(x, y) = eye_map(x, y) + 1
            If eye_map(x, y) > p_color Then
              p_color = p_color + 1 ‘ increment saturation counter
              status.Text = “Building graded display, ” & Int(p_{—}
              color * 100 / 2000) & “% done, sample # ” & Int(i)
            End If
          End If
        Next y
      Next x
      If p_color > 2000 Then GoTo int_exit
    End If
  Next i
int_exit:
  ‘
  ‘ move intensity data into display window
  ‘
  status.Text = “building final intensity graded display - paused”
  eye.Cls
  For x = 1 To eye.width
    For y = 1 To eye.Height
      p_color = eye_map(x, y)
      If p_color > 255 Then p_color = 255
      If p_color > 0 Then
        p_color = 256 − ((1 − p_color / 256) \hat{ } 4) * 256
        p_color = p_color * (&H1& + &H100 + &H10000)
        eye.PSet (x, y), p_color
      End If
    Next y
  Next x
End Sub
```

Although an embodiment of the present invention has been shown and described, it will be appreciated by those skilled in the art that changes may be made in these embodiments without departing from the principles and spirit of the invention, the scope of which is defined in the claims and their equivalents.

For example, while the present invention has been described as using a digital PLL, those of ordinary skill in the art will recognize that the routines and calculations forming the digital PLL could be implemented with HDL (Hardware Design Language) in an ASIC. Further, such an ASIC could be physically located inside of a DSO's case or as an add-on component (external or internal).

What is claimed is:

1. A digital storage oscilloscope comprising:
a port for receiving a signal to be analyzed, the signal having an embedded clock signal; and
a processor configured by a software phase locked loop to recover the embedded clock signal from the signal.

2. The digital storage oscilloscope, as set forth in claim 1, wherein the processor is further configured to generate an eye diagram of the signal based on the recovered embedded clock signal.

3. The digital storage oscilloscope, as set forth in claim 2, wherein the eye diagram is an intensity graded eye diagram.

4. The digital storage oscilloscope, as set forth in claim 2, further comprising a display to display the eye diagram.

5. The digital storage oscilloscope, as set forth in claim 1, wherein the processor is configured to identify trigger points in the recovered embedded clock signal.

6. The digital storage oscilloscope, as set forth in claim 5, wherein the processor is further configured to generate an eye diagram of the signal based on the recovered embedded clock signal wherein the creation of the eye diagram is delayed for at least one trigger point to allow the processor to accurately recover the embedded clock signal.

7. The digital storage oscilloscope, as set forth in claim 5, wherein trigger points are identified based on a rising edge in the recovered clock signal.

8. The digital storage oscilloscope, as set forth in claim 1, wherein the processor creates a first data structure referencing trigger points versus time.

9. The digital storage oscilloscope, as set forth in claim 8, wherein the first data structure is a one dimensional array with a value indicative of the presence of a trigger point for each time unit.

10. The digital storage oscilloscope, as set forth in claim 9, wherein each entry on the array is either a “1” indicating the presence of a trigger point or a “0” indicating the lack of a trigger point.

11. The digital storage oscilloscope, as set forth in claim 10, wherein the processor creates a second data structure referencing the voltage of the signal versus time and wherein the time covered by the first data structure is coextensive with the time covered by the second data structure.

12. A digital storage oscilloscope comprising:
a port for receiving a signal to be analyzed, the signal having an embedded clock signal; and
a processor configured by software to recover the embedded clock signal from the signal and to generate an eye diagram of the signal based on the recovered embedded clock signal.

13. The digital storage oscilloscope, as set forth in claim 12, wherein the processor is configured to recover the embedded clock signal using a software-based digital phase locked loop.

14. The digital storage oscilloscope, as set forth in claim 12, wherein the eye diagram is an intensity graded eye diagram.

15. The digital storage oscilloscope, as set forth in claim 12, further comprising a display to display the eye diagram.

16. The digital storage oscilloscope, as set forth in claim 12, wherein the processor is configured to identify trigger points in the recovered embedded clock signal and wherein the trigger points are used to generate the eye diagram of the signal.

17. The digital storage oscilloscope, as set forth in claim 16, wherein the processor is configured to pause the creation of the eye diagram for at least one trigger point to allow the processor to accurately recover the embedded clock signal.

18. The digital storage oscilloscope, as set forth in claim 16, wherein trigger points are identified based on a rising edge in the recovered clock signal.

19. The digital storage oscilloscope, as set forth in claim 16, wherein the processor creates a first data structure referencing trigger points versus time.

20. The digital storage oscilloscope, as set forth in claim 19, wherein the first data structure is a one dimensional array with a value indicative of the presence of a trigger point for each time unit.

21. The digital storage oscilloscope, as set forth in claim 20, wherein each entry on the array is either a “1” indicating the presence of a trigger point or a “0” indicating the lack of a trigger point.

22. The digital storage oscilloscope, as set forth in claim 21, wherein the processor creates a second data structure referencing the voltage of the signal versus time and wherein the time covered by the first data structure is coextensive with the time covered by the second data structure.

23. A method of generating an eye diagram of a signal having an embedded clock signal, the method comprising:
representing the signal as a first set of digital values related to the voltage of the signal as a function of time;
recovering the embedded clock signal from the first set of digital values using a digital PLL so as to generate a second set of digital values indicative of trigger points as a function of time;
extracting a plurality of series of values from the first set of digital values based on the identification of trigger points in the second set of digital values; and
generating an eye diagram by overlapping a display of an indication of each of the plurality of series of values.

24. The method, as set forth in claim 23, wherein each of the plurality of series of values is centered around a time at which a trigger point has been identified.

25. The method, as set forth in claim 23, wherein the step of recovering comprises:
generating a second set of digital values indicative of trigger points as a function of time using a software PLL to recover the embedded clock signal from the first set of digital values.

26. The method, as set forth in claim 23, wherein the step of extracting a plurality of series of values comprises:
for each series of values:
identifying a trigger point in the second set of digital values;
determining a time of the trigger point in the second set of digital values; and
extracting a series of digital values that encompasses the time of the trigger point in the first series of digital values.

27. A digital storage oscilloscope comprising:
means for receiving a signal having an embedded clock signal;
means for converting the signal into a series of digital values; and
digital PLL means for extracting trigger points from the embedded clock signal.

28. The digital storage oscilloscope, as set forth in claim 27, wherein the digital PLL means comprises a processor operating in accordance with a software PLL.

29. The digital storage oscilloscope, as set forth in claim 27, wherein the digital PLL comprises an ASIC configured to implement a digital PLL algorithm.

30. A digital storage oscilloscope comprising:
a port for receiving a signal to be analyzed, the signal having an embedded clock signal; and
a digital phase locked loop to recover the embedded clock signal from the signal.

31. The digital storage oscilloscope, as set forth in claim 30, wherein the digital phase locked loop comprises a software PLL.

32. The digital storage oscilloscope, as set forth in claim 30, wherein the digital phase locked loop comprises a digital hardware PLL.

33. The digital storage oscilloscope, as set forth in claim 30, further comprising means to identify trigger points in the recovered embedded clock signal.

34. The digital storage oscilloscope, as set forth in claim 30, further comprising:
a processor configured to generate an eye diagram of the signal based on the recovered embedded clock signal.

35. The digital storage oscilloscope, as set forth in claim 34, wherein the eye diagram is an intensity graded eye diagram.

36. The digital storage oscilloscope, as set forth in claim 34, further comprising a display to display the eye diagram.

37. The digital storage oscilloscope, as set forth in claim 34, wherein the creation of the eye diagram is delayed for a predetermined period of time to allow the processor to accurately recover the embedded clock signal.
